(19) United States
(12) Patent Application Publication
(10) Pub. No.: US 2025/0338431 A1
(43) Pub. Date: Oct. 30, 2025

(54) COOLING FAN, ELECTRONIC DEVICE, AND METHOD FOR MANUFACTURING ELECTRONIC DEVICE

(71) Applicant: Sony Interactive Entertainment Inc., Tokyo (JP)

(72) Inventors: Takayuki HACHIYA, Tokyo (JP); Keiichi AOKI, Tokyo (JP); Yuta TAMAKI, Chiba (JP); Mitsuharu MORISHITA, Tokyo (JP); Shinya HIROMITSU, Tokyo (JP)

(73) Assignee: Sony Interactive Entertainment Inc., Tokyo (JP)

(21) Appl. No.: 18/855,385

(22) PCT Filed: Apr. 11, 2022
(86) PCT No.: PCT/JP2022/017537

§ 371 Date: Oct. 9, 2024

(51) Int. Cl. H05K 7/20

(52) U.S. Cl. CPC H05K 7/20172

(57) ABSTRACT

There is provided an electronic device that prevents atmospheric components and dust from sticking to parts mounted on a circuit substrate of a cooling fan. The cooling fan has the circuit substrate arranged, with respect to a motor, in a direction along an axis line of the motor. At least one of a switching element, a control IC for controlling the switching element, a protection diode, a protection capacitor, and a shunt resistor is mounted on the circuit substrate. An air intake port of the electronic device is positioned away from the motor in a radial direction of the motor. The at least one of the parts is arranged on the opposite side of the air intake port with a plane interposed therebetween, the plane passing through the axis line of the motor.

### TECHNICAL FIELD

The present disclosure relates to a cooling fan, an electronic device, and a method for manufacturing the electronic device.

### BACKGROUND ART

A cooling fan is arranged inside an electronic device such as a game machine, a personal computer, or a server computer to cool heat-generating elements including a central processing unit (CPU) and a graphics processing unit (GPU) mounted on a circuit substrate of the cooling fan. The electronic device has air intake ports formed on its exterior members to introduce outside air. PTL 1 cited below discloses an example of such electronic devices,

### CITATION LIST

### Patent Literature

### [PTL 1]

PCT Patent Publication No. WO2021/193879

### SUMMARY

### Technical Problem

The cooling fan has a circuit substrate mounted with various electronic parts such as a switching element (field effect transistor (FET)) for controlling the current supplied to a motor and a control integrated circuit (IC) for controlling the switching element in response to signals input from the outside. Depending on the relative positional relation between the air intake port formed on the exterior member and the cooling fan and on the usage environment of the electronic device, atmospheric components and dust in the air introduced from the air intake port may attach to the electronic parts on the circuit substrate.

### Solution to Problem

An electronic device proposed in the present disclosure includes a cooling fan and an exterior member inside of which the cooling fan is arranged and which has an air intake port. The cooling fan has fins, a motor for rotating the fins, and a circuit substrate mounted with a plurality of parts for driving the motor, the circuit substrate being arranged, with respect to the motor, in a direction along an axis line of the motor. The plurality of parts include at least one of a switching element for controlling a current supplied to the motor, a control IC for controlling the switching element, a protection element for stabilizing a power supply voltage, and a resistor for measuring the current supplied to the motor. The air intake port is positioned away from the motor in a radial direction thereof. At least one of the plurality of parts is arranged on the opposite side of the air intake port with a plane interposed therebetween, the plane passing through the axis line of the motor. This electronic device can reduce the atmospheric components and dust sticking to the electronic parts on the circuit substrate of the cooling fan.

An electronic device proposed in the present disclosure includes fins, a motor for rotating the fins, a circuit substrate mounted with a plurality of parts for driving the motor, the circuit substrate being arranged, with respect to the motor, in a direction along an axis line of the motor, at least one cable, and a connection part mounted on the circuit substrate and connected with the at least one cable. The plurality of parts include at least one of a switching element for controlling a current supplied to the motor, a control IC for controlling the switching element, a protection element for stabilizing a power supply voltage, and a resistor for measuring the current supplied to the motor. The at least one of the plurality of parts is arranged on the same side as the connection part relative to a plane normal to straight line connecting the axis line of the motor with the connection part, the plane further passing through the axis line. This cooling fan makes it easy to implement an arrangement that, when the electronic device is equipped with the cooling fan, reduces the atmospheric components and dust sticking to the electronic parts on the circuit substrate of the cooling fan.

A method of manufacturing an electronic device proposed in the present disclosure includes a step of preparing a cooling fan that has fins, a motor for rotating the fins, and a circuit substrate mounted with a plurality of parts for driving the motor, the circuit substrate being arranged, with respect to the motor, in a direction along an axis line of the motor, a step of preparing an exterior member having an air intake port for introducing air, the exterior member housing the cooling fan, and an assembly step of arranging the cooling fan inside the exterior member in such a manner that the air intake port is positioned away from the motor in a radial direction thereof, The parts include at least one of a switching element for controlling a current supplied to the motor, a control IC for controlling the switching element, a protection element for stabilizing a power supply voltage, and a resistor for measuring the current supplied to the motor. The assembly step involves arranging the cooling fan inside the exterior member in such a manner that the at least one of the parts is positioned on the opposite side of the air intake port with a plane interposed therebetween, the plane passing through the axis line of the motor. This manufacturing method can reduce the atmospheric components and dust sticking to the electronic parts on the circuit substrate of the cooling fan.

### BRIEF DESCRIPTION OF DRAWINGS

FIG. 1 is a perspective view depicting an exemplary electronic device proposed in the present disclosure.

FIG. 2A is an exploded perspective view of a device main body, an upper exterior panel, and a lower exterior panel of the electronic device in FIG. 1 as viewed obliquely from above.

FIG. 2B is an exploded perspective view of the device main body, the upper exterior panel, and the lower exterior panel of the electronic device of FIG. 1 as viewed obliquely from below.

FIG. 3 is a bottom view of the device main body, indicating a region where a cooling fan is arranged.

FIG. 4 is a sectional view of the electronic device, taken on line IV-IV in FIG. 3.

FIG. 5A is a bottom view of the cooling fan.

FIG. 5B is a sectional view of the cooling fan, taken on line Vb-Vb in FIG. 5A.

FIG. 6 is a plan view of a circuit substrate included in the cooling fan.

FIG. 7 is a circuit diagram depicting typical main parts mounted on the circuit substrate in FIG. 6.

### DESCRIPTION OF EMBODIMENT

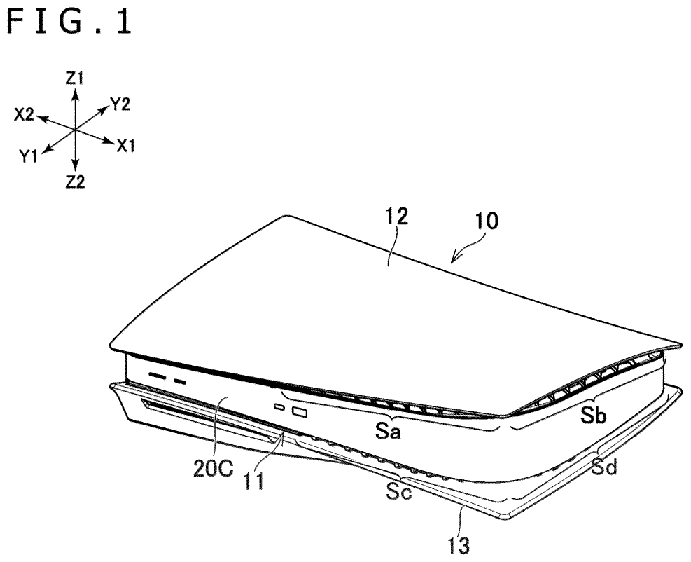

What follows is a description of an electronic device proposed in the present disclosure with reference to the accompanying drawings. In the description that follows, it is assumed in FIG. 1 that X1 and X2 stand for the right direction and the left direction, respectively, Y1 and Y2 for the forward direction and the backward direction, respectively, and Z1 and 22 for the upward direction and the downward direction, respectively. These directions are defined solely to explain the shapes of, and relative positional relations between, elements (parts, members, and portions) of an electronic device 10. As such, these directions are not intended to restrict the posture of the electronic device 10 in use.

The electronic device 10 is, for example, an entertainment apparatus functioning as a game machine or as an audio-visual device. The electronic device 10 outputs, to a display apparatus such as a television set, moving image data generated by execution of game programs, video and audio data acquired over networks, or video and audio data obtained from recording media such as optical disks. The electronic device may alternatively be a personal computer or a server computer.

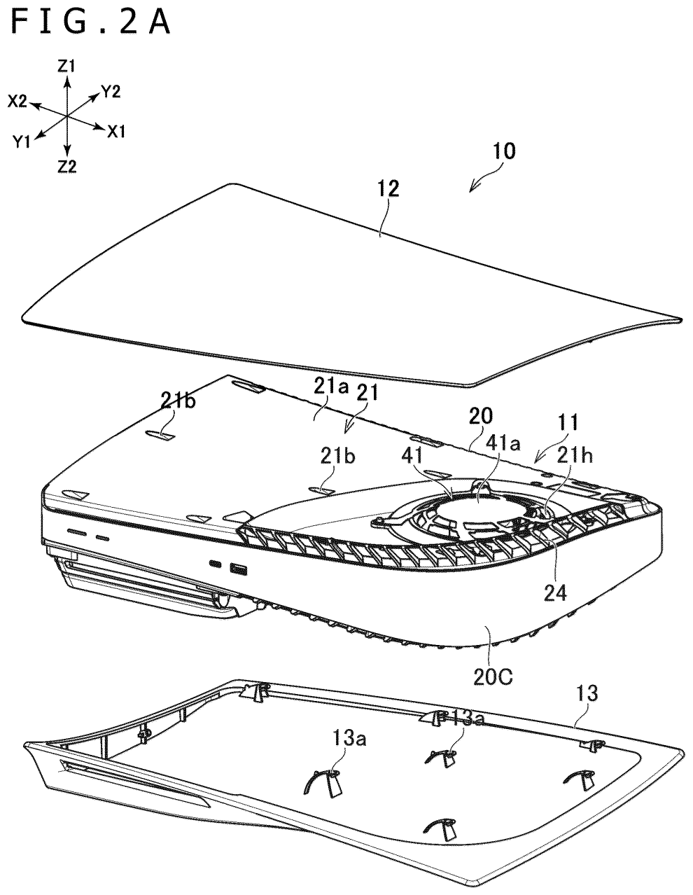

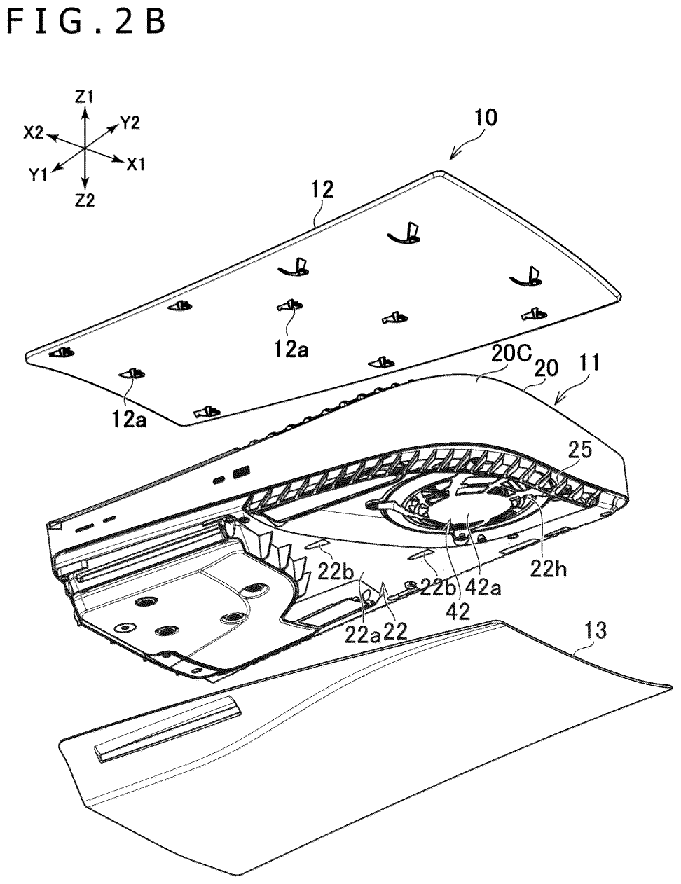

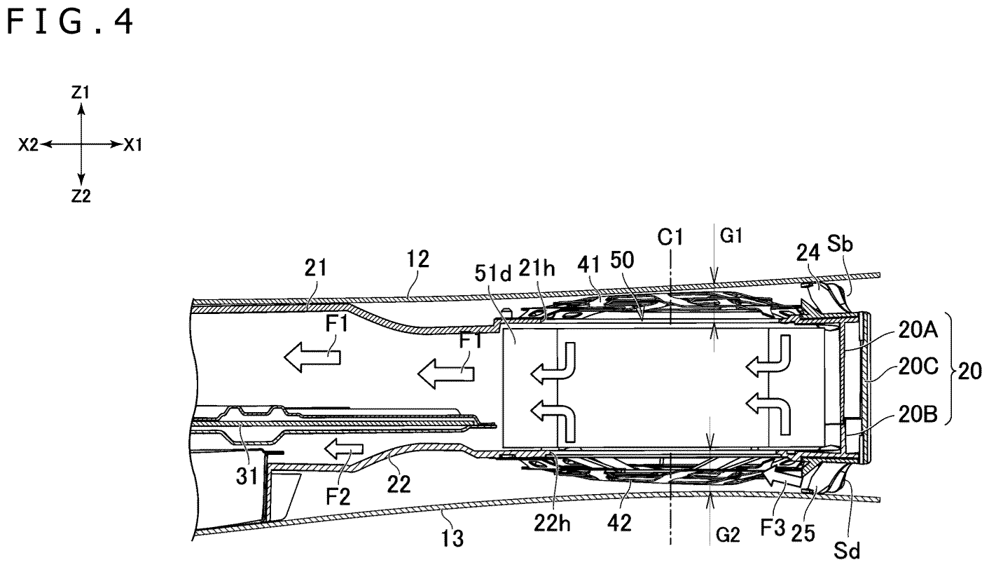

The electronic device 10 has a device main body 11 (see FIG. 2A). The device main body 11 has a housing 20. As depicted in FIG. 4, the housing 20 houses a circuit substrate 31. The circuit substrate 31 is mounted with various electronic parts such as a CPU and a GPU. The housing 20 also has undepicted radiators (heat sink, heat pipe, etc.) and a cooling fan 50. The radiators are connected to the electronic parts such as the CPU. The cooling fan 50 introduces outside air into the housing 20, creating, the housing 20, airflows that pass through the radiators. The housing 20 has flow paths that create airflows F1 and F2 inside. (In FIG. 4, hollow arrows indicate the airflows.)

The housing 20 may include a plurality of members that combine with each other. For example, as depicted in FIG. 4, the housing 20 may have an upper housing 20A and a lower housing 20B that combine with each other in the up-down direction. The housing 20 may also have an exterior panel 20C (see FIG. 2A) surrounding front and side surfaces of the upper housing 20A and the lower housing 20B.

### Exterior Members

The housing 20 has an upper wall 21 (see FIG. 2A) covering the upper side of the circuit substrate 31, the radiators, and the like and a lower wall 22 (see FIG. 2B) covering the lower side of the circuit substrate 31, the radiators, and the like. As depicted in FIG. 2A, the device main body 11 has an upper exterior panel 12 that covers an upper surface 21a (outer surface of the upper wall 21) of the device main body 11 and that is attached to the upper surface 21a. As depicted in these drawings, the upper exterior panel 12 may be large enough in size to cover the entire upper surface 21a of the device main body 11, or small enough to cover solely a portion of the upper surface 21a (e.g., an air intake port 21h, to be discussed later).

Also, as depicted in FIG. 2B, the device main body 11 has a lower exterior panel 13 that covers a lower surface 22a (outer surface of the lower wall 22) of the device main body 11 and that attached to the lower surface 22a. As with the upper exterior panel 12, the lower exterior panel 13 may also be large enough in size to cover the entire lower surface 22a of the device main body 11, or small enough to cover merely a portion of the lower surface 22a (e.g., an air intake port 22h, to be discussed later).

The upper exterior panel 12 and the lower exterior panel 13 are removably attached to the device main body 11. The upper exterior panel 12 has attachment parts 12a (see FIG. 2B) removably attached to a plurality of attachment parts 21b (see FIG. 2A) formed on the upper surface 21a of the device main body 11. The lower exterior panel 13 has attachment parts 13a (see FIG. 2A) removably attached to a plurality of attachment parts 22b (see FIG. 2B) formed on the lower surface 22a of the device main body 11.

### Air Intake System of the Exterior Members

As depicted in FIG. 4, the air intake port 21h is formed on the upper wall 21 of the housing 20. (The air intake port 21h will be referred to as an upper housing air intake port hereunder.) Also, the air intake port 22h is formed on the lower wall 22 of the housing 20. (The air intake port 22h will be referred to as a lower housing air intake port hereunder.) As will be discussed later, the cooling fan 50 is arranged in such a manner that an axis line C1 passing through its center of rotation is oriented in the up-down direction. The upper housing air intake port 21h is formed on the upper side of the cooling fan 50, and the lower housing air intake port 22h is formed on the lower side of the cooling fan 50. The air intake port 21h is an opening on the upper wall 21 of the housing 20. At least a portion of the air intake port 21h may be formed to overlap on the upper side of the cooling fan 50, allowing the cooling fan 50 to be exposed through at least the portion of the air intake port 21h. The air intake port 22h is an opening on the lower wall 22 of the housing 20. At least a portion of the air intake port 22h may be formed to overlap on the lower side of the cooling fan 50, allowing the cooling fan 50 to be exposed through at least the portion of the air intake port 22h.

The electronic device 10 has the upper exterior panel 12, the lower exterior panel 13, and the housing 20 as its exterior members. As depicted in FIG. 1, the exterior members have air intake ports Sa, Sb, Sc, and Sd for introducing outside air into the electronic device 10, As depicted in FIG. 4, a gap G1 is formed between the upper housing air intake port 21h and the upper exterior panel 12. The gap G1 functions as an airflow path leading from the air intake ports Sa and Sb to the upper housing air intake port 21h. (The gap G1 will be referred to as an upper air intake path hereunder.) That is, the air intake ports Sa and Sb are positioned at an end of the upper air intake path G1 formed between the upper surface 21a of the housing 20 and the upper exterior panel 12, in a manner opening toward the outside of the exterior members. Further, a gap G2 is formed between the lower housing air intake port 22h and the lower exterior panel 13. The gap G2 functions as an airflow path leading from the air intake ports Sc and Sd to the lower housing air intake port 22h. (The gap G2 will be referred to as a lower air intake path hereunder.) That is, the air intake ports Sc and Sd are positioned at an end of the lower air intake path G2 formed between the lower surface 22a of the housing 20 and the lower exterior panel 13, in a manner opening toward the outside of the exterior members.

The upper air intake path G1 (see FIG. 4) extends in a direction intersecting with (substantially normal to) the axis line C1 of the cooling fan 50, That is, the upper air intake path G1 extends in the radial direction of the cooling fan 50 along the upper wall 21 of the housing 20. Further, the air intake ports Sa and Sb between the upper exterior panel 12 and the upper wall 21 of the housing 20 are opened in a direction intersecting with the axis line C1. For example, as depicted in FIG. 1, the air intake port Sa may be opened to the front side of the electronic device 10, and the air intake port Sb may be opened to the right side of the electronic device 10. The air intake ports Sa and Sb may be connected with each other to form a single air intake port across a corner of the electronic device 10. The air intake ports Sa and Sb may be equipped with a louver member 24 (see FIG. 2A). The louver member 24 serves to suppress exposure of the upper air intake path G1 and the upper housing air intake port 21h.

Likewise, the lower air intake path G2 (see FIG. 4) extends in a direction intersecting with (substantially normal to) the axis line C1 of the cooling fan 50. That is, the lower air intake path G2 extends in the radial direction of the cooling fan 50 along the lower wall 22 of the housing 20, Further, the air intake ports Sc and Sd between the lower exterior panel 13 and the lower wall 22 of the housing 20 are opened in a direction intersecting with the axis line C1. For example, as depicted in FIG. 1, the air intake port Sc may be opened to the front side of the electronic device 10, and the air intake port Sd may be opened to the right side of the electronic device 10. The air intake ports Sc and Sd may be connected with each other to form a single air intake port across a corner of the electronic device 10. The air intake ports Sc and Sd may be equipped with a louver member 25 (see FIG. 2B). The louver member 25 serves to suppress exposure of the lower air intake path G2 and the lower housing air intake port 22h.

When the cooling fan 50 is driven, air is introduced from the upper air intake ports Sa and Sb into the upper air intake path G1. The air flows inside the upper air intake path G1 in a direction intersecting with (substantially normal to) the axis line C1 of the cooling fan 50, before being drawn from the upper housing air intake port 21h into the housing 20.

Further, when the cooling fan 50 is driven, air is also introduced from the lower air intake ports Sc and Sd into the lower air intake path G2. The air flows inside the lower air intake path G2 in a direction intersecting with (substantially normal to) the axis line C1 of the cooling fan 50, before being drawn from the lower housing air intake port 22h into the housing 20.

The structures of the exterior members of the electronic device 10 are not limited to the exemplary structures depicted in FIGS. 1 through 4. For example, the two directions in which to open the air intake ports Sa and Sb between the upper exterior panel 12 and the upper wall 21 of the housing 20 need not be normal to each other. For example, the air intake ports between the upper exterior panel 12 and the upper wall 21 of the housing 20 may be opened only to the front side or to the right side. Likewise, two directions in which to open the air intake ports Sc and Sd between the lower exterior panel 13 and the lower wall 22 of the housing 20 need not be normal to each other. For example, the air intake ports between the lower exterior panel 13 and the lower wall 22 of the housing 20 may be opened only to the front side or to the right side.

Further, in another example, the exterior members may be formed in a box-like shape. In this case, the exterior members need not have the upper exterior panel 12 and the lower exterior panel 13.

As depicted in FIG. 2A, the upper housing air intake port 21h may be covered by a protection plate 41 with a plurality of openings formed thereon. An outer peripheral edge of the protection plate 41 may be attached to the edge of the upper housing air intake port 21h. The protection plate 41 may be curved in such a manner that its central part 41a is positioned higher than the outer peripheral edge of the protection plate 41. This can reduce the air resistance caused by the protection plate 41.

Likewise, the lower housing air intake port 22h may be covered by a protection plate 42 (see FIG. 2B) with a plurality of openings formed thereon. An outer peripheral edge of the protection plate 42 may be attached to the edge of the lower housing air intake port 22h. The protection plate 42 may be curved in such a manner that its central part 42a is positioned lower than the outer peripheral edge of the protection plate 42. This can reduce the air resistance caused by the protection plate 42.

### Cooling Fan

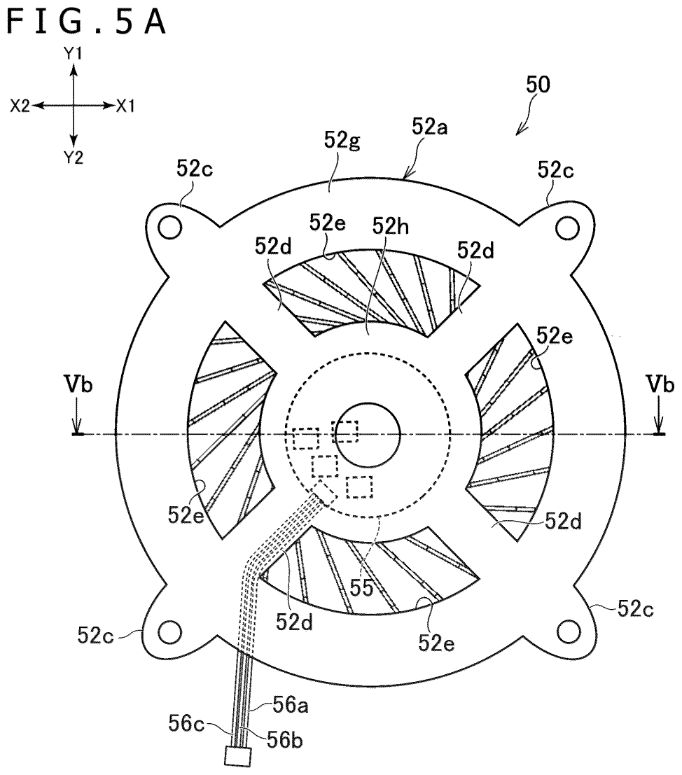

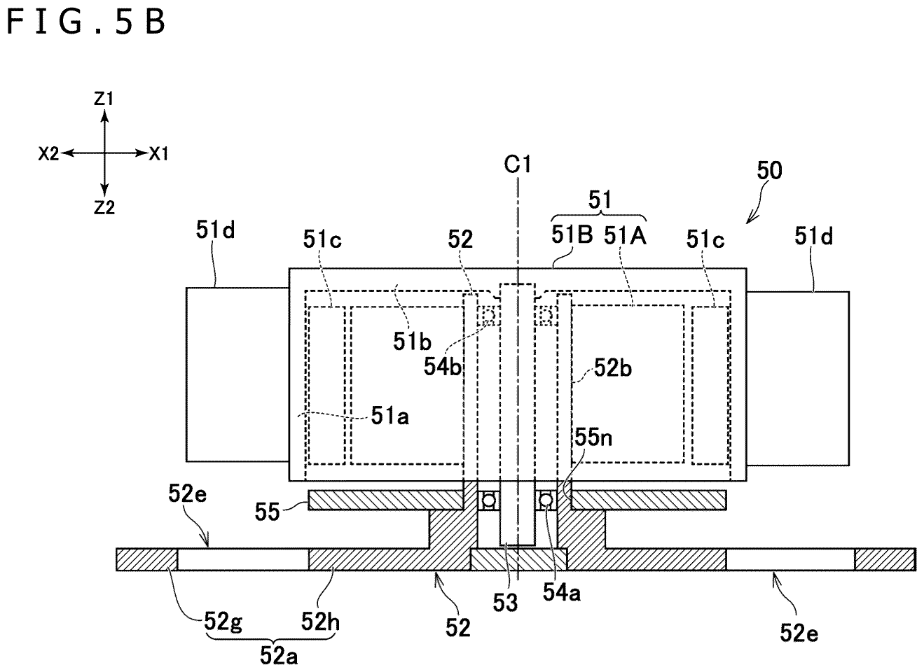

As depicted in FIG. 5B, the cooling fan 50 has a motor 51, a base member 52, a rotating shaft 53, a circuit substrate 55, and cables 56a, 56b, and 56c (see FIG. 5A). As discussed above, the cooling fan 50 is arranged in such a manner that the axis line C1 along its center of rotation is oriented in the up-down direction of the electronic device 10.

As depicted in FIG. 5B, the motor 51 has a stator 51A including a coil, and a rotor 51B that is rotatable around the stator 51A. A plurality of fins 51d are formed on the outer peripheral surface of the rotor 51B. The rotor 51B has a tube part 51a surrounding the outer periphery of the stator 51A, and an end wall part 51b formed at an end of the tube part 51a in a manner covering the stator 51A. A plurality of permanent magnets 51c are attached to the inside of the tube part 51a. The core of the stator 51A and the permanent magnets 51c are opposed to one another in the radial direction of the motor 51. The rotating shaft 53 is fixed to the end wall part 51b of the rotor 51B and is rotatable in one piece with the rotor 51B.

As depicted in FIG. 5B, the base member 52 has a base plate part 52a arranged in the direction of the axis line C1 relative to the motor 51. Also, the base member 52 has a support tube part 52b inside of which the rotating shaft 53 is arranged. The support tube part 52b supports the rotating shaft 53 by means of bearings 54a and 54b arranged inside of the support tube part 52b. Also, the stator 51A is fixed to the outer periphery of the support tube part 52b. The base member 52 is formed by sheet metal processing performed on a metal plate.

As depicted in FIG. 5A, the base plate part 52a has a circular outer ring part 52g and another circular inner ring part 52h. A plurality of attachment parts 52c (four attachment parts 52c in FIG. 5A) are formed on the outer periphery of the outer ring part 52g. The attachment parts 52c are attached to the edge of the above-described lower housing air intake port 22h by means of fixing implements such as screws and bolts.

As depicted in FIG. 5A, the base member 52 has a plurality of bridges 52d extending from an inner edge of the outer ring part 52g toward the inner ring part 52h. The plurality of bridges 52d are formed with gaps therebetween in the rotation direction of the motor 51. An opening 52e is formed between two bridges 52d adjacent to each other in the rotation direction.

When the cooling fan 50 is driven, i.e., when the rotor 51B is rotated, air is introduced through the opening 52e from the side of the base member 52 of the cooling fan 50 (from the lower side of the example in the present disclosure), and air is also drawn from the opposite side of the base member 52 (from the upper side of the example in the present disclosure).

### Circuit Substrate of the Cooling Fan

As depicted in FIG. 5B, the circuit substrate 55 is arranged on the side of the motor 51 (upper side in the drawing) relative to the base plate part 52a. That is, the circuit substrate 55 is arranged between the inner ring part 52h of the base plate part 52a and the stator 51A of the motor 51. The circuit substrate 55 has an opening 55n at its center. Arranged inside the opening 55n are the support tube part 52b of the base member 52 and the rotating shaft 53. The circuit substrate 55 is attached to the base member 52.

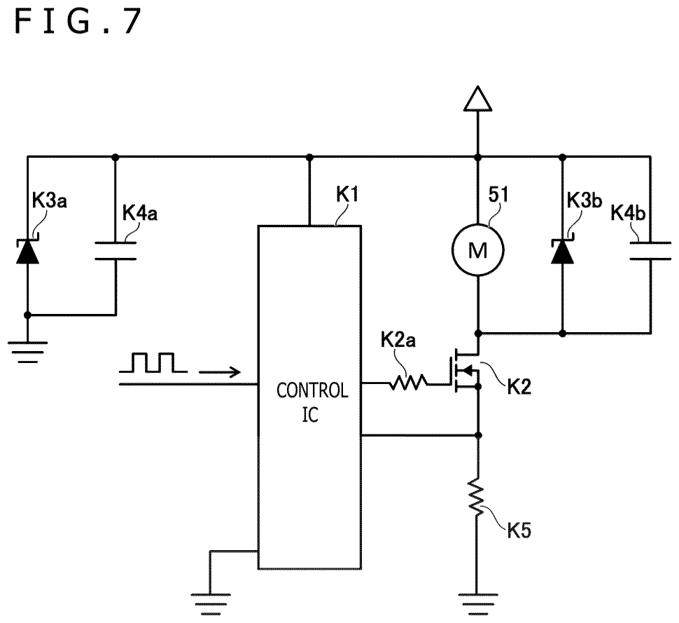

The circuit substrate 55 is mounted with a plurality of parts for driving the motor 51. Specifically, as depicted in FIG. 7, the circuit substrate 55 is mounted with a switching element K2 for controlling the current supplied to the motor 51 and a control IC (K1) for controlling the switching element K2. For example, a metal-oxide-semiconductor field-effect transistor (MOSFET) may be used as the switching element K2. The switching element K2 may have a gate to be connected with the control IC (K1), a drain to be connected with the motor 51, and a source to be grounded. The control IC (K1) outputs signals to turn on and off the switching element K2, That is, the control IC (K1) outputs PWM signals to the switching element K2. Based on instructions from the outside (e. g., from a processor mounted on the circuit substrate 31) and on the output of a rotation sensor attached to the motor 51, the control IC (K1) drives the switching element K2 to control the current supplied to the motor 51. A resistor (gate resistor) K2a may be interposed between the control IC (K1) and the gate of the switching element K2, which is a MOSFET. The resistor K2a serves to stabilize the current supplied to the motor 51, by the action of the switching element K2.

Also, the circuit substrate 55 may be mounted with a protection element for stabilizing the power supply voltage for the control IC (K1) and/or the motor 51. Specifically, as depicted in FIG. 7, a protection diode K3a may be mounted on the circuit substrate 55 as an exemplary protection element. The protection diode K3a is connected between the power supply and a ground in series. Also, the protection diode K3a is connected in parallel with the control IC (K1) and motor 51 to protect them against excessive currents applied thereto. Further, the circuit substrate 55 may be mounted with a protection diode K3b as another exemplary protection element. The protection diode K3b is connected, for example, between the power supply and the switching element K2 in series. Note that, differently from the example in FIG. 7, only one of the two protection diodes K3a and K3b may be mounted on the circuit substrate 55. For example, solely the protection diode K3a connected to the ground may be mounted on the circuit substrate 55.

Also, the circuit substrate 55 may be mounted with a protection capacitor K4a as an exemplary protection element. The protection capacitor K4a is connected between the power supply and the ground in series. For example, the protection capacitor K4a is connected, for example, in parallel with the control IC (K1) and the motor 51 to keep constant the voltage applied thereto. Further, the circuit substrate 55 may be mounted with a protection capacitor K4b as another exemplary protection element. The protection capacitor K4b is connected between the power supply and the switching element K2 in series. Note that, differently from the example in FIG. 7, only one of the two protection capacitors K4a and K4b may be mounted on the circuit substrate 55. For example, solely the protection capacitor K4a connected to the ground may be mounted on the circuit substrate 55.

The circuit substrate 55 may be mounted with a resistor for measuring the current being supplied to the motor 51, i.e., a shunt resistor K5. The shunt resistor K5 may be connected, for example, to the switching element K2 and to the ground.

In the description that follows, in a case where the above-mentioned eight parts K1, K2, K2a, K3a, K3b, K4a, K4b, and K5 need not be distinguished from one another, these parts are designated by reference sign K. The parts K may be mounted on either the upper surface (on the side of the motor 51) or the lower surface (on the side of the base plate part 52a) of the circuit substrate 55.

The plurality of cables 56a, 56b, and 56c include a cable for supplying a drive current to the motor 51. The cables 56a, 56b, and 56c also include a cable for supplying the control IC (K1) with control signals from the outside (e.g., from the processor mounted on the circuit substrate 31) for driving the motor 51. For example, the control signals designate the rotation speed of the cooling fan 50. Whereas FIG. 5A indicates three cables 56a, 56b, and 56c, four cables may alternatively be provided (e.g., two power supply cables and two signal cables).

### Arrangements of the Parts on the Circuit Substrate

When the cooling fan 50 is driven, air is introduced from the lower air intake ports Sc and Sd into the lower air intake path G2 (see FIG. 4). An airflow F3 produced in the lower air intake path G2 flows in a direction intersecting with the axis line C1 of the cooling fan 50, moving toward the motor 51. As a result, those parts on the circuit substrate 55 which are close to the air intake ports Sc and Sd are directly hit by the airflow F3, which may cause atmospheric components and dust in the airflow F3 to stick to those parts.

For this reason, in the examples explained in the present disclosure, the parts K mounted on the circuit substrate 55 are arranged in such a manner as not to be directly hit by the airflow F3 as much as possible. Such arrangements of the parts K are described below in detail.

### Positional Relation between the Air Intake Ports and the Parts

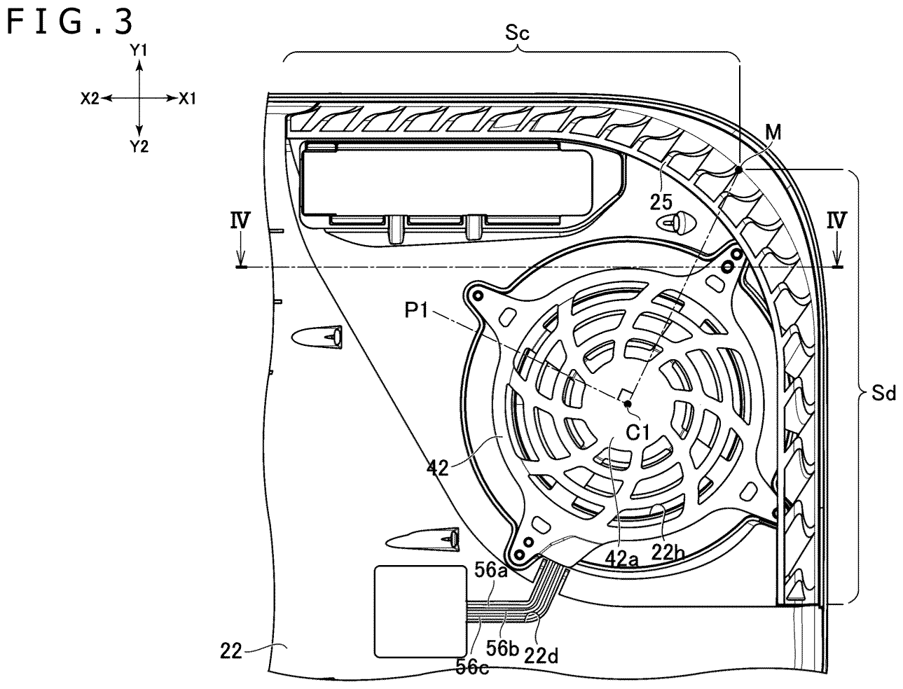

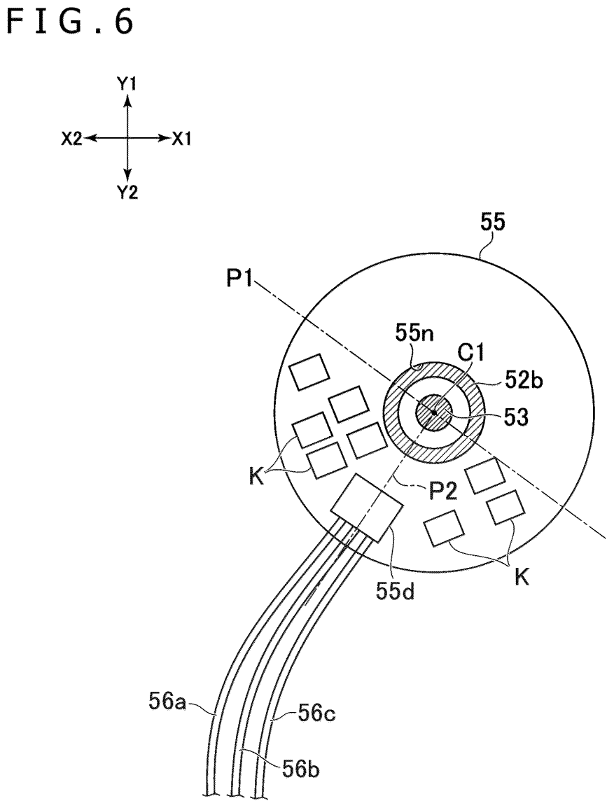

The air intake ports Sc and Sd are positioned away from the axis line C1 of the motor 51 in the radial direction of the motor 51. In FIGS. 3 and 6, a plane P1 passes through the axis line C1 of the motor 51. At least one of the plurality of parts described above (control IC (K1), switching element K2, protection diodes K3a and K3b, and protection capacitors K4a and K4b) mounted on the circuit substrate 55 is positioned on the opposite side of the air intake ports Sc and Sd with the plane P1 interposed therebetween. This arrangement of the parts (K1, K2, K2a, K3a, K3b, K4a, and K4b) can reduce the atmospheric components and dust sticking to the parts.

The plane P1 may be normal to a straight line that passes through the axis line C1 of the motor 51 in a manner connecting a middle portion M (see FIG. 3) between the air intake ports Sc and Sd with the axis line C1.

The plane P1 may also be normal to a straight line that connects the axis line C1 with the position where the width of the air intake ports Sc and Sd is the largest. (Here, the width of the air intake ports Sc and Sd is a width in a direction normal to the opening direction of the air intake ports Sc and Sd. In the example in FIG. 1, the width is the distance between the upper surface 21a of the housing 20 and the upper exterior panel 12.)

Also, the plane P1 may be normal to a straight line connecting the axis line C1 with the position where the amount of air passing through the air intake ports Sc and Sd per unit time is the largest (the position where the speed of airflow is the highest).

In one example of the electronic device 10, the main parts among the above eight parts K may be positioned on the opposite side of the air intake ports Sc and Sd with the plane Pl interposed therebetween. For example, the control IC (K1), the switching element K2, the grounded protection diode K3a, the grounded protection capacitor K4a, and the shunt resistor K5 may be positioned on the opposite side of the air intake ports Sc and Sd with the plane P1 interposed therebetween. This arrangement can effectively reduce the atmospheric components and dust sticking to the parts and also lessen the effects of the atmospheric components and the like to the parts with respect to the motor 51 being driven. In this case, the protection diode K3b and the protection capacitor K4b need not be mounted on the circuit substrate 55. Alternatively, the protection diode K3b and the protection capacitor K4b may be arranged on the same side as the air intake ports Sc and Sd with the plane P1 interposed therebetween.

In another example, all of the plurality of parts K described above (specifically, control IC (K1), switching element K2, gate resistor K2a, protection diodes K3a and K3b, protection capacitors K4a and K4b, and shunt resistor K5) may be positioned on the opposite side of the air intake ports Sc and Sd with the plane P1 interposed therebetween. This arrangement can more effectively reduce the atmospheric components and dust sticking to the parts K and also lessen effectively the effects of the atmospheric components and the like sticking to the parts K with respect to the motor 51 being driven.

Differently from the above, one of the plurality of parts described above (control IC (K1), switching element K2, gate resistor K2a, protection diodes K3a and K3b, protection capacitors K4a and K4b, and shunt resistor K5) may be positioned on the opposite side of the air intake ports Sc and Sd with the plane P1 interposed therebetween. For example, the control IC (K1) or the switching element K2, the most important of the plurality of parts K described above, may be positioned on the opposite side of the air intake ports Sc and Sd with the plane P1 interposed therebetween. This arrangement can reduce the effects of the atmospheric components and the like sticking to the parts with respect to the motor 51 being driven. In this case, the remaining parts (K2a, K3a, K3b, K4a, K4b, and K5) may be positioned either on the same side as the air intake ports Sc and Sd relative to the plane P1 or on the opposite side of the air intake ports Sc and Sd with the plane P1 interposed therebetween.

Atmospheric components and dust tend to stick to large-sized parts. For this reason, the parts positioned on the opposite side of the air intake ports Sc and Sd with the plane P1 interposed therebetween may be the parts which are larger in size than the remaining parts. That is, the largest in size among the plurality of parts K may be positioned on the opposite side of the air intake ports Sc and Sd with the plane P1 interposed therebetween. In this case, the remaining parts K may be positioned either on the same side as the air intake ports Sc and Sd relative to the plane P1 or on the opposite side of the air intake ports Sc and Sd with the plane P1 interposed therebetween,

Atmospheric components and dust also tend to stick to tall parts on the surface of the circuit substrate 55. For this reason, the parts arranged on the opposite side of the air intake ports Sc and Sd with the plane P1 interposed therebetween may be taller than the other parts. That is, the tallest of the plurality of parts K may be positioned on the opposite side of the air intake ports Sc and Sd with the plane P1 interposed therebetween. In this case, the remaining parts K may be positioned either on the same side as the air intake ports Sc and Sd relative to the plane P1 or on the opposite side of the air intake ports Sc and Sd with the plane P1 interposed therebetween.

Differently from the above, two of the plurality of parts described above (control IC (K1), switching element K2, gate resistor K2a, diodes protection K3a and K3b, protection capacitors K4a and K4b, and shunt resistor K5) may be positioned on the opposite side of the air intake ports Sc and Sd with the plane P1 interposed therebetween. For example, the control IC (K1) and the switching element K2, which are critical for driving the motor 51, may be positioned on the opposite side of the air intake ports Sc and Sd with the plane P1 interposed therebetween. This arrangement can effectively lessen the effects of the atmospheric components and the like sticking to the parts with respect to the motor 51 being driven. Further, the remaining parts (K2a, K3a, K3b, K4a, K4b, and K5) may be positioned either on the same side as the air intake ports Sc and Sd relative to the plane P1 or on the opposite side of the air intake ports Sc and Sd with the plane P1 interposed therebetween.

In further example, three of the plurality of parts described above (control IC (K1), switching element K2, gate resistor K2a, protection diodes K3a and K3b, protection capacitors K4a and K4b, and shunt resistor K5) may be positioned on the opposite side of the air intake ports Sc and Sd with the plane P1 interposed therebetween. For example, one of the gate resistor K2a, the protection diodes K3a and K3b, the protection capacitors K4a and K4b, and the shunt resistor K5; the control IC (K1); and the switching element K2 may be positioned on the opposite side of the air intake ports Sc and Sd with the plane P1 interposed therebetween. This arrangement can more effectively lessen the effects of the atmospheric components and the like sticking to the parts with respect to the motor 51 being driven. In this case, the remaining parts may be positioned either on the same side as the air intake ports Sc and Sd relative to the plane P1 or on the opposite side of the air intake ports Sc and Sd with the plane P1 interposed therebetween.

In a still further example, the parts K arranged on the opposite side of the air intake ports Sc and Sd with the plane P1 interposed therebetween may be parts not packaged with insulating materials such as resin. For example, in a case where the shunt resistor K5 and the capacitors K4a and K4b are not packaged, these parts K4a, K4b, and K5 may be arranged on the opposite side of the air intake ports Sc and Sd with the plane P1 interposed therebetween. In this case, the parts K packaged with insulating materials such as resin may be positioned either on the same side as the air intake ports Sc and Sd relative to the plane P1 or on the opposite side of the air intake ports Sc and Sd with the plane P1 interposed therebetween. Such an arrangement of the parts can lessen the effects of the atmospheric components on the non-packaged parts.

### Positional Relation between the Connection Part and the Parts

The circuit substrate 55 has a connection part connected with one end of each of the cables 56a, 56b, and 56c. A connector may be attached to one end of each of the cables 56a, 56b, and 56c. In this case, as depicted in FIG. 6, the circuit substrate 55 may be equipped with a connector 55d as the above-mentioned connection part to which the end connectors of the cables 56a, 56b, and 56c are removably attached. Differently from this, one end of each of the cables 56a, 56b, and 56c may alternatively be soldered to the circuit substrate 55. In this case, the soldered portions function as the above connection part. The other end of each of the cables 56a, 56b, and 56c may be connected, for example, to another circuit substrate 31 housed in the housing 20.

As depicted in FIG. 3, a receiving groove 22d is formed on the lower wall 22 of the housing 20. The cables 56a, 56b, and 56c are laid in the receiving groove 22d and extend into the housing 20.

The connection part to which one end of each of the cables 56a, 56b, and 56c is connected may be positioned on the opposite side of the air intake ports Sc and Sd relative to the plane P1. In FIG. 6, the plane P1 is also normal to a straight line P2 connecting the axis line C1 of the motor 51 with the connector 55d (connection part). Further, the connector 55d is positioned on the opposite side of the air intake ports Sc and Sd with the plane P1 interposed therebetween. Arranging the connector 55d in this manner makes it easy electrically to connect the circuit substrate 55 to the device main body 11. The arrangement also makes it easy to lay the cables 56a, 56b, and 56c in a manner eliminating air resistance to the airflow produced between the lower exterior panel 13 and the lower wall 22 of the housing 20.

In the examples explained in the present disclosure, at least one of the plurality of parts described above (control IC (K1), switching element K2, gate resistor K2a, protection diodes K3a and K3b, and protection capacitors K4a and K4b) mounted on the circuit substrate 55 is arranged on the same side as the connector 55d, which serves as the connection part, relative to the plane P1. This arrangement of the plurality of parts (K1, K2, K2a, K3a, K3b, K4a, K4b, and K5) and of the connector 55d facilitates installation, in the electronic device 10, of the cooling fan 50 for reducing the atmospheric components and dust sticking to the parts. That is, when the electronic device 10 is equipped with the cooling fan 50 in such a manner that the connector 55d is positioned far from the air intake ports Sc and Sd as depicted in FIGS. 3 and 6, the atmospheric components and dust sticking to these parts can be reduced.

The connector 55d is positioned, for example, on the opposite side of the air intake ports Sc and Sd with the axis line C1 interposed therebetween. In other words, when the circuit substrate 55 is viewed from above, the connector 55d may intersect with a straight line connecting the axis line C1 with the middle portion M between the air intake ports Sc and Sd.

Also, the connector 55d may be positioned on the opposite side of the position where the width of the air intake ports Sc and Sd is the largest, with the axis line C1 interposed therebetween. In other words, the connector 55d may intersect with a straight line connecting the axis line C1 with the position where the width of the air intake ports Sc and Sd is the largest. (Here, the width of the air intake ports Sc and Sd is the width in a direction normal to the opening direction of the air intake ports Sc and Sd. In the example in FIG. 1, this width is the distance in the up-down direction between the upper surface 21a of the housing 20 and the upper exterior panel 12.)

Further, the connector 55d may be positioned on the opposite side of the position where the amount of air introduced through the air intake ports Sc and Sd per unit time is the largest (the position where the speed of airflow is the highest), with the axis line C1 interposed therebetween. In other words, the connector 55d may intersect with a straight line connecting the axis line C1 with the position where the amount of air introduced through the air intake ports Sc and Sd per unit time is the largest.

In one example of the cooling fan 50, the main parts among the above eight parts K may be arranged on the same side as the connector 55d relative to the plane P1. For example, the control IC (K1), the switching element K2, the grounded protection diode K3a, the grounded protection capacitor K4a, and the shunt resistor K5 may be arranged on the same side as the connector 55d relative to the plane P1. When the cooling fan 50 is mounted in the electronic device 10, this arrangement can effectively reduce the atmospheric components and dust sticking to these parts (K1, K2, K2a, K3a, K4a, and K5) and can thereby lessen the effects of the atmospheric components and dust sticking to the parts with respect to the motor 51 being driven. In this case, the protection diode K3b and the protection capacitor K4b need not be mounted on the circuit substrate 55. Alternatively, the protection diode K3b and the protection capacitor K4b may be arranged on the opposite side of the connector 55d relative to the plane P1.

In another example of the cooling fan 50, all the above eight parts (specifically, control IC (K1), switching element K2, gate resistor K2a, protection diodes K3a and K3b, protection capacitors K4a and K4b, and shunt resistor K5) may be arranged on the same side as the connector 55d relative to the plane P1. This arrangement can more effectively reduce the atmospheric components and dust sticking to these parts K when the cooling fan 50 is mounted in the electronic device 10 and can thereby lessen effectively the effects of the atmospheric components and dust sticking to the parts K on the motor 51 being driven.

Differently from the above, one of the plurality of parts described above (control IC (K1), switching element K2, gate resistor K2a, protection diodes K3a and K3b, protection capacitors K4a and K4b, and shunt resistor K5) may be arranged on the same side as the connector 55d relative to the plane P1. For example, the control IC (K1) or the switching element K2, the most important of the plurality of parts K described above, may be arranged on the same side as the connector 55d relative to the plane P1. This arrangement can lessen the effects of the atmospheric components and the like sticking to the parts with respect to the motor 51 being driven. In this case, the remaining parts (K3a, K3b, K4a, K4b, and K5) may be arranged either on the opposite side of the connector 55d relative to the plane P1 or on the same side as the connector 55d with respect to the plane P1.

Atmospheric components and dust tend to stick to large-sized parts. For this reason, the parts arranged on the same side as the connector 55d may be larger in size than the other parts. That is, the largest in size among the plurality of parts K may be positioned on the same side as the connector 55d relative to the plane P1. In this case, the remaining parts may be arranged either on the opposite side of the connector 55d with the plane P1 interposed therebetween or on the same side as the connector 55d relative to the plane P1.

Atmospheric components and dust also tend to stick to tall parts on the surface of the circuit substrate 55. For this reason, the parts arranged on the same side as the connector 55d relative to the plane PI may be taller than the other parts. That is, the tallest of the plurality of parts K may be positioned on the same side as the connector 55d relative to the plane P1. In this case, the remaining parts K may be arranged either on the opposite side of the connector 55d relative to the plane P1 or on the same side as the connector 55d with respect to the plane P1.

Differently from the above, two of the plurality of parts described above (control IC (K1), switching element K2, gate resistor K2a, protection diodes K3a and K3b, protection capacitors K4a and K4b, and shunt resistor K5) may be arranged on the same side as the connector 55d relative to the plane P1. For example, the control IC (K1) and the switching element K2, which are critical for driving the motor 51, may be arranged on the same side as the connector 55d relative to the plane P1. This arrangement can effectively lessen the effects of the atmospheric components and the like sticking to the parts with respect to the motor 51 being driven. In this case, the remaining parts (K2a, K3a, K3b, K4a, K4b, and K5) may be arranged either on the opposite side of the connector 55d with the plane P1 interposed therebetween or on the same side as the connector 55d relative to the plane P1.

In a further example, three of the plurality of parts described above (control IC (K1), switching element K2, gate resistor K2a, protection diode K3a, protection capacitor K4a, and shunt resistor K5) may be arranged on the same side as the connector 55d relative to the plane P1. For example, one of the gate resistor K2a, the protection diode K3a, the protection capacitor K4a, and the shunt resistor K5; the control IC (K1); and the switching element K2 may be arranged on the same side as the connector 55d relative to the plane Pl. This arrangement can more effectively lessen the effects of the atmospheric components and the like sticking to the parts with respect to the motor 51 being driven. In this case, the remaining parts may be arranged either on the opposite side of the connector 55d with the plane P1 interposed therebetween or on the same side as the connector 55d relative to the plane P1.

In a still further example, the parts arranged on the same side as the connector 55d relative to the plane P1 may be parts not packaged with insulating materials such as resin. For example, in a case where the shunt resistor K5 and the protection capacitors K4a and K4b are not packaged, these parts K4a, K4b, and K5 may be arranged on the same side as the connector 55d relative to the plane P1. In this case, the parts packaged with insulating materials such as resin may be arranged either on the opposite side of the connector 55d relative to the plane P1 or on the same side as the connector 55d with respect to the plane P1. Such an arrangement of the parts can lessen the effects of atmospheric components on the non-packaged parts.

An exemplary method of manufacturing the electronic device 10 is described below. First, there are prepared the cooling fan 50 and the exterior members for housing the cooling fan 50 (housing 20, upper exterior panel 12, and lower exterior panel 13). At this time, the circuit substrate 31 and the radiators are also prepared for arrangement inside the exterior members.

The cooling fan 50 to be prepared has the fins 51d, the motor 51. for rotating the fins 51d, and the circuit substrate 55. The circuit substrate 55 is arranged, with respect to the motor 51, in a direction along the axis line C1 of the motor 51. The plurality of parts K for driving the motor 51 are mounted on the circuit substrate 55. The exterior members have the air intake ports Sc and Sd for introducing air.

In an assembly step, the cooling fan 50 is arranged inside the exterior members in such a manner that the air intake ports Sc and Sd are positioned away from the motor 51 in the radial direction of the motor 51. Also in the assembly step, the cooling fan 50 is arranged inside the exterior members in such a manner that at least one of the plurality of parts (the above parts K1, K2, K3a, K3b, K4a, K4b, and K5) is positioned on the opposite side of the air intake ports Sc and Sd with the plane P1 interposed therebetween, the plane P1 passing through the axis line C1 of the motor 51. Further, in the assembly step, as described above, the cooling fan 50 may be arranged inside the exterior members in such a manner that all main parts (parts K1, K2, K3a, K4a, and K5) to be mounted on the circuit substrate 55 are positioned on the opposite side of the air intake ports Sc and Sd with the plane P1 interposed therebetween, the plane P1 passing through the axis line C1 of the motor 51.

Further, in another example of the assembly step, the cooling fan 50 may be arranged inside the exterior members in such a manner that two or three of the plurality of parts K are positioned on the opposite side of the air intake ports Sc and Sd with the plane P1 interposed therebetween. In a further example of the assembly step, the cooling fan 50 may be arranged inside the exterior members in such a manner that the largest in size among the plurality of parts K is positioned on the opposite side of the air intake ports Sc and Sd with the plane P1 interposed therebetween.

### Conclusion

The electronic device 10 explained above has the cooling fan 50 and the exterior members (housing 20, upper exterior panel 12, and lower exterior panel 13) including the air intake ports Sc and Sd. The cooling fan 50 has the fins 51d, the motor 51 for rotating the fins 51d, and the circuit substrate 55 mounted with the plurality of parts K for driving the motor 51 and arranged, with respect to the motor 51, in a direction along the axis line C1 of the motor 51. The plurality of parts K include the switching element K2 for controlling the current supplied to the motor 51, the control IC (K1) for controlling the switching element K2, the protection diodes K3a and d K3b and the protection capacitors K4a and K4b for stabilizing the power supply voltage, and the shunt resistor K5 for measuring the current supplied to the motor 51. The air intake ports Sc and Sd are positioned away from the motor 51 in the radial direction of the motor 51. At least one of the plurality of parts (K1, K2, K3a, K3b, K4a, K4b, and K5) is arranged on the opposite side of the air intake ports Sc and Sd with the plane P1 interposed therebetween, the plane P1 passing through the axis line C1 of the motor 51. This arrangement of the parts in the electronic device 10 can reduce the atmospheric components and dust sticking to the parts K.

Note that, in the electronic device described in the present disclosure, two or three of the plurality of parts K described above may be arranged on the opposite side of the air intake ports Sc and Sd with the plane P1 interposed therebetween, the plane P1 passing through the axis line C1. Further, the remaining parts may be positioned on the same side as the air intake ports Sc and Sd relative to the plane P1.

The cooling fan 50 explained above has the motor 51 for rotating the fins 51d; the circuit substrate 55 mounted with the plurality of parts K for driving the motor 51 and arranged, with respect to the motor 51, in a direction along the axis line C1 of the motor 51; the cables 56a, 56b, and 56c; and the connector (connection part) 55d that is mounted on the circuit substrate 55 and that has the cables 56a, 56b, and 56c connected thereto. The plurality of parts K include the switching element K2 for controlling the current supplied to the motor 51, the control IC (K1) for controlling the switching element K2, the protection diodes K3a and K3b and the protection capacitors K4a and K4b for stabilizing the power supply voltage, and the shunt resistor K5 for measuring the current supplied to the motor 51. At least one of the plurality of parts (K1, K2, K3a, K3b, K4a, K4b, and K5) is arranged on the same side as the connector 55d relative to the plane P1 which passes through the axis line C1 and which is normal to the straight line P2 connecting the axis line C1 of the motor 51 with the connector 55d. Note that a plane normal to the straight line P2 connecting the axis line C1 with the connector 55d may be different from the plane P1. In this case, one or more of the above parts (e.g., control IC (K1) and switching element K2) desired to avoid the direct hit of air from the air intake ports Sc and Sd of the electronic device 10 may be positioned on the same side as the connector 55d relative to the plane normal to the straight line P2.

The above arrangement of the parts (K1, K2, K3a, K3b, K4a, K4b, and K5) and the connector 55d makes it easy to arrange the cooling fan 50 in the electronic device 10 in a manner reducing the atmospheric components and dust sticking to the parts K.

Note that, with respect to the cooling fan described in the present disclosure, two or three of the plurality of parts described above (K1, K2, K3a, K3b, K4a, K4b, and K5) may be arranged on the same side as the connector (connection part) 55d relative to the plane P1 passing through the axis line C1. Further, the remaining parts may be positioned on the opposite side of the connector 55d with respect to the plane P1.

### Others

Note that the electronic device and the cooling fan described in the present disclosure are not limited to the electronic device 10 and the cooling fan 50 discussed above.

For example, the exterior members of the electronic device 10 have the air intake ports Sa and Sb (see FIG. 1) provided in the upper part thereof and the air intake ports Sc and Sd (see FIG. 1) arranged in the lower part thereof. However, the exterior members of the electronic device 10 may alternatively have only the air intake ports Sc and Sd (see FIG. 1) arranged in the lower part thereof, i.e., the air intake ports Sc and Sd on the side where the base member 52 is arranged, while dispensing with the air intake ports Sa and Sa in the upper part.

Further, the circuit substrate 55 is mounted with the control IC (K1), the switching element K2, the gate resistor K2a, the protection diodes K3a and K3b, the capacitors K4a and K4b, and the shunt resistor K5. However, as long as the cooling fan 50 stays functional, the cooling fan 50 may dispense with some of these parts K1, K2, K2a, K3a, K3b, K4a, K4b, and K5.

### REFERENCE SIGNS LIST

10: Electronic device
11: Device main body
12: Upper exterior panel
12a: Attachment part
13: Lower exterior panel
13a: Attachment part
20: Housing
20A: Upper housing
20B: Lower housing
20C: Exterior panel
21: Upper wall
21a: Upper surface
21b: Attachment part
21h: Upper housing air intake port
22: Lower wall
22a: Lower surface
22b: Attachment part
22d: Receiving groove
22h: Lower housing air intake port
24, 25: Louver member
31: Circuit substrate
41, 42: Protection plate
50: Cooling fan
51: Motor
51A: Stator
51B; Rotor
51a: Tube part
51b: End wall part
51c: Permanent magnet
51d: Fin
52: Base member
52a: Base plate part
52b: Support tube part
52c: Attachment part
52d: Bridge
52e: Opening
52g: Outer ring part
52h: Inner ring part
53: Rotating shaft
54a, 54b: Bearing
55: Circuit substrate
55d: Connector
55n: Opening
56a, 56b, 56c: Cable
G1: Upper air intake path
G2: Lower air intake path
K1: Control IC (part)
K2: Switching element (part)
K2a: Gate resistor (part)
K3a, K3b: Protection diode (part)
K4a, K4b: Protection capacitor (part)
K5: Shunt resistor (part)
Sa, Sb, Sc, Sd: Air intake port

1. An electronic device comprising:
a cooling fan; and
an exterior member inside of which the cooling fan is arranged,
wherein the cooling fan has fins, a motor for rotating the fins, and a circuit substrate mounted with a plurality of parts for driving the motor, the circuit substrate being arranged, with respect to the motor, in a direction along an axis line of the motor,
the plurality of parts include at least one of a switching element for controlling a current supplied to the motor, a control integrated circuit for controlling the switching element, a protection element for stabilizing a power supply voltage, and a resistor for measuring the current supplied to the motor,
the exterior member has an air intake port that introduces air and that is positioned away from the motor in a radial direction thereof, and
the at least one of the plurality of parts is arranged on an opposite side of the air intake port with a plane interposed therebetween, the plane passing through the axis line of the motor.

2. The electronic device according to claim 1,
wherein the plurality of parts include at least two of the switching element, the control integrated circuit, the protection element, and the resistor, and
the at least two of the plurality of parts are arranged on the opposite side of the air intake port with the plane interposed therebetween.

3. The electronic device according to claim 1,
wherein the plurality of parts include at least three of the switching element, the control integrated circuit, the protection element, and the resistor, and
the at least three of the plurality of parts are arranged on the opposite side of the air intake port with the plane interposed therebetween.

4. The electronic device according to claim 1,
wherein the plurality of parts include the switching element, the control integrated circuit, the protection element, and the resistor, and
the switching element, the control integrated circuit, the protection element, and the resistor are arranged on the opposite side of the air intake port with the plane interposed therebetween.

5. The electronic device according to claim 1,
wherein the at least one of the switching element, the control integrated circuit, the protection element, and the resistor is the largest in size among the switching element, the control integrated circuit, the protection element, and the resistor.

6. A cooling fan for an electronic device, the cooling fan comprising:
fins;
a motor for rotating the fins;
a circuit substrate mounted with a plurality of parts for driving the motor, the circuit substrate being arranged, with respect to the motor, in a direction along an axis line of the motor;
at least one cable; and
a connection part mounted on the circuit substrate and connected with the at least one cable,
wherein the plurality of parts include at least one of a switching element for controlling a current supplied to the motor, a control integrated circuit for controlling the switching element, a protection element for stabilizing a power supply voltage, and a resistor for measuring the current supplied to the motor, and
the at least one of the plurality of parts is arranged on a same side as the connection part relative to a plane normal to a straight line connecting the axis line of the motor with the connection part, the plane further passing through the axis line.

7. The cooling fan according to claim 6,
wherein the plurality of parts include at least two of the switching element, the control integrated circuit, the protection element, and the resistor, and
the at least two of the plurality of parts are arranged on the same side as the connection part relative to the plane.

8. The cooling fan according to claim 6,
wherein the plurality of parts include at least three of the switching element, the control integrated circuit, the protection element, and the resistor, and
the at least three of the plurality of parts are arranged on the same side as the connection part relative to the plane.

9. The cooling fan according to claim 6,
wherein the plurality of parts include the switching element, the control integrated circuit, the protection element, and the resistor, and
the switching element, the control integrated circuit, the protection element, and the resistor are arranged on the same side as the connection part relative to the plane.

10. The cooling fan according to claim 6,
wherein at least one of the switching element, the control integrated circuit, the protection element, and the resistor is the largest in size among the switching element, the control integrated circuit, the protection element, and the resistor.

11. A method of manufacturing an electronic device, the method comprising:
a step of preparing a cooling fan that has fins, a motor for rotating the fins, and a circuit substrate mounted with a plurality of parts for driving the motor, the circuit substrate being arranged, with respect to the motor, in a direction along an axis line of the motor;
a step of preparing an exterior member having an air intake port for introducing air, the exterior member housing the cooling fan; and
an assembly step of arranging the cooling fan inside the exterior member in such a manner that the air intake port is positioned away from the motor in a radial direction thereof,
wherein the plurality of parts include at least one of a switching element for controlling a current supplied to the motor, a control integrated circuit for controlling the switching element, a protection element for stabilizing a power supply voltage, and a resistor for measuring the current supplied to the motor, and
the assembly step involves arranging the cooling fan inside the exterior member in such a manner that the at least one of the plurality of parts is positioned on an opposite side of the air intake port with a plane interposed therebetween, the plane passing through the axis line of the motor.
